(19) United States
(12) Patent Application Publication
(10) Pub. No.: US 2016/0066413 A1
(43) Pub. Date: Mar. 3, 2016

(54) DISPLAY ASSEMBLY

(71) Applicant: Samsung Electronics Co., Ltd., Gyeonggi-do (KR)

(72) Inventors: Jung Hyun KIM, Gyeonggi-do (KR); Joon Gyu LEE, Gyeonggi-do (KR); Sang Yong EOM, Gyeonggi-do (KR); Jae Seung CHOI, Gyeonggi-do (KR)

(21) Appl. No.: 14/843,137

(22) Filed: Sep. 2, 2015

(30) Foreign Application Priority Data
Sep. 2, 2014 (KR) 10-2014-0116325

(51) Int. Cl. H05K 1/02; H05K 13/00; H05K 5/00

(52) U.S. Cl. CPC H05K 1/028; H05K 5/0017; H05K 1/0274; H05K 13/0023

(57) ABSTRACT

A display apparatus comprising: a flexible display panel including a display view area and a dummy area around the display view area, wherein the flexible display panel are bended at least on the display view area; a polarizing plate disposed over the display view area of the flexible display panel and between the flexible display panel and a protective panel; the protective panel disposed over the polarizing plate; and a step coverage base disposed over the dummy area of the flexible display panel, alongside to the polarizing plate.

### CLAIM OF PRIORITY

This application claims the benefit under 35 U.S.C. §119(a) of a Korean patent application filed on Sep. 2, 2014 in the Korean Intellectual Property Office and assigned Serial number 10-2014-0116325, the entire disclosure of which is hereby incorporated by reference.

### TECHNICAL FIELD

The present disclosure herein relates to electronic devices in general, and more particularly to a display assembly.

### BACKGROUND

Due to the development of electronic technology, various types of electronic devices have been developed and spread. Especially, the supply of electronic devices such as smartphones, notebook PCs, Tablet PCs, digital cameras, smart TVs, etc. has been expanded and also displays are mostly applied to recently developed electronic devices.

As the uses of electronic devices are increased, user needs for more various functions are increased. Accordingly, as each manufacturer's efforts to meet the user needs are increased, products with new functions that are not provided before, for example, 3D contents, FHD displays, flexible displays, curved (or bended) displays, and so on, have been introduced one after another.

A display includes a display area where an image is displayed and a dummy area where no image is displayed, and the dummy area has less components included in comparison to the display area and thus may be vulnerable to external pressure or force. For example, a momentary pressure may be applied to the dummy area during a user's use of an electronic device or a manufacturing process of a display.

Accordingly, disconnection may occur in a signal line in a display panel, a fine crack may occur in a display panel, or air or moisture may penetrate a display panel to deteriorate a state of a display.

### SUMMARY

According to aspects of the disclosure, a display is provided comprising: a flexible display panel including a display view area and a dummy area around the display view area, wherein the flexible display panel are bended at least on the display view area; a polarizing plate disposed over the display view area of the flexible display panel and between the flexible display panel and a protective panel; the protective panel disposed over the polarizing plate; and a step coverage base disposed over the dummy area of the flexible display panel, alongside to the polarizing plate.

According to aspects of the disclosure, an electronic device is provided comprising a display including: a flexible display panel including a display view area and a dummy area around the display view area, wherein the flexible display panel are bended at least on the display view area; a polarizing plate disposed over the display view area of the flexible display panel and between the flexible display panel and a protective panel; the protective panel disposed over the polarizing plate; and a step coverage base disposed over the dummy area of the flexible display panel, alongside to the polarizing plate.

According to aspects of the disclosure, a method for manufacturing a display comprising: disposing a polarizing plate over a display view area of a flexible display panel, the flexible display panel including the display view area and a dummy area around the display view area, wherein the flexible display panel are bended at least on the display view area; disposing a protective panel over the polarizing plate; and disposing a step coverage base over the dummy area of the flexible display panel, alongside to the polarizing plate.

### BRIEF DESCRIPTION OF THE DRAWINGS

FIG. 1A is a diagram showing A plan view of an example of an electronic device, according to various embodiments of the present disclosure;

FIG. 1B is a diagram showing a first sectional view of the electronic device of FIG. 1A, according to various embodiments of the present disclosure;

FIG. 1C is a diagram showing a second sectional view of the electronic device of FIG. 1A, according to various embodiments of the present disclosure;

FIG. 2 is a diagram of an example of a display panel according to various embodiments of the present disclosure;

FIG. 3A is a diagram showing a sectional view of a portion of an electronic device, according to various embodiments of the present disclosure;

FIG. 3B is a diagram showing a sectional view of a portion of an electronic device, according to various embodiments of the present disclosure;

FIG. 3C is a diagram showing a sectional view of a portion of an electronic device, according to various embodiments of the present disclosure;

FIG. 3D is a diagram showing a sectional view of a portion of an electronic device, according to various embodiments of the present disclosure;

FIG. 3E is a diagram showing a sectional view of a portion of an electronic device, according to various embodiments of the present disclosure;

FIG. 4A is a diagram showing a plan view of an example of an electronic device, according to various embodiments of the present disclosure;

FIG. 4B is a diagram showing a sectional view of the electronic device of FIG. 4A, according to various embodiments of the present disclosure;

FIG. 5A is a diagram showing a sectional view of a portion of an electronic device, according to various embodiments of the present disclosure;

FIG. 5B is a diagram showing a sectional view of a portion of an electronic device, according to various embodiments of the present disclosure;

FIG. 6 is a block diagram of an example of an electronic device according to various embodiments of the present disclosure;

FIG. 7 is a diagram showing a perspective view of an example of an electronic device according to various embodiments of the present disclosure.

### DETAILED DESCRIPTION

Hereinafter, various embodiments of the present disclosure are disclosed with reference to the accompanying drawings. Various modifications are possible in various embodiments of the present disclosure and specific embodiments are illustrated in drawings and related detailed descriptions are listed. However, this does not limit various embodiments of the present disclosure to a specific embodiment and it should be understood that the present disclosure covers all the modifications, equivalents, and/or replacements of this disclosure provided they come within the scope of the appended claims and their equivalents. With respect to the descriptions of the drawings, like reference numerals refer to like elements.

The term “include,” “comprise,” and “have”, or “may include,” or “may comprise” and “may have” used herein indicates disclosed functions, operations, or existence of elements but does not exclude other functions, operations or elements. Additionally, in various embodiments of the present disclosure, the terms “include” or “have” will be listed hereinafter with reference to the accompanying drawings. However, this does not limit various embodiments of the present disclosure to a specific embodiment and it should be understood that the present disclosure covers all the modifications, equivalents, and/or alternatives of this disclosure provided they come within the scope of the appended claims and their equivalents. With respect to the descriptions of the drawings, like reference numerals refer to like elements.

The term “include,” “comprise,” and “have”, or “may include,” or “may comprise” and “may have” used herein indicates disclosed functions, operations, or existence of elements but does not exclude other functions, operations or elements.

For instance, the expression “A or B”, or “at least one of A or/and B” may indicate include A, B, or both A and B. For instance, the expression “A or B”, or “at least one of A or/and B” may indicate (1) at least one A, (2) at least one B, or (3) both at least one A and at least one B.

The terms such as “1st”, “2nd”, “first”, “second”, and the like used herein may refer to modifying various different elements of various embodiments of the present disclosure, but do not limit the elements. For instance, “a first user device” and “a second user device” may indicate different users regardless of the order or the importance. For example, a first component may be referred to as a second component and vice versa without departing from the scope of the present disclosure.

In various embodiments of the present disclosure, it will be understood that when a component (for example, a first component) is referred to as being “(operatively or communicatively) coupled with/to” or “connected to” another component (for example, a second component), the component can be directly connected to the other component or connected through another component (for example, a third component). In various embodiments of the present disclosure, it will be understood that when a component (for example, a first component) is referred to as being “directly connected to” or “directly access” another component (for example, a second component), another component (for example, a third component) does not exist between the component (for example, the first component) and the other component (for example, the second component).

In the specification, it will be understood that when a component is referred to as being ‘on’ another component, it can be directly on the other component, or intervening layers may also be present.

The expression “configured to” used in various embodiments of the present disclosure may be interchangeably used with “suitable for”, “having the capacity to”, “designed to”, “adapted to”, “made to”, or “capable of” according to a situation, for example. The term “configured to” may not necessarily mean “specifically designed to” in terms of hardware. Instead, the expression “a device configured to” in some situations may mean that the device and another device or part are “capable of”. For example, “a processor configured (or set) to perform A, B, and C” in a phrase may mean a dedicated processor (for example, an embedded processor) for performing a corresponding operation or a generic-purpose processor (for example, a CPU or application processor) for performing corresponding operations by executing at least one software program stored in a memory device.

Terms used in various embodiments of the present disclosure are used to describe specific embodiments of the present disclosure, and are not intended to limit the scope of other embodiments. The terms of a singular form may include plural forms unless they have a clearly different meaning in the context. Otherwise indicated herein, all the terms used herein, which include technical or scientific terms, may have the same meaning that is generally understood by a person skilled in the art. In general, the terms defined in the dictionary should be considered to have the same meaning as the contextual meaning of the related art, and, unless clearly defined herein, should not be understood abnormally or as having an excessively formal meaning. In any cases, even the terms defined in this specification cannot be interpreted as excluding embodiments of the present disclosure.

According to various embodiments of the present disclosure, electronic devices may include at least one of smartphones, tablet personal computers (PCs), mobile phones, video phones, electronic book (e-book) readers, desktop personal computers (PCs), laptop personal computers (PCs), netbook computers, workstation server, personal digital assistants (PDAs), portable multimedia player (PMPs), MP3 players, mobile medical devices, cameras, and wearable devices (for example, smart glasses, head-mounted-devices (HMDs), electronic apparel, electronic bracelets, electronic necklaces, electronic appcessories, electronic tattoos, smart mirrors, and smart watches).

According to some embodiments of the present disclosure, an electronic device may be smart home appliances. The smart home appliances may include at least one of, for example, televisions, digital video disk (DVD) players, audios, refrigerators, air conditioners, cleaners, ovens, microwave ovens, washing machines, air cleaners, set-top boxes, home automation control panels, security control panels, TV boxes (e.g., Samsung HomeSync™, Apple TV™ or Google TV™), game consoles (for example, Xbox™ and PlayStation™), electronic dictionaries, electronic keys, camcorders, and electronic picture frames.

According to some embodiments of the present disclosure, an electronic device may include at least one of various medical devices supporting call forwarding service (for example, various portable measurement devices (for example, glucometers, heart rate meters, blood pressure meters, temperature meters, etc.), magnetic resonance angiography (MRA) devices, magnetic resonance imaging (MRI) devices, computed tomography (CT) devices, medical imaging devices, ultrasonic devices, etc.), navigation devices, global positioning system (GPS) receivers, event data recorders (EDRs), flight data recorders (FDRs), vehicle infotainment devices, marine electronic equipment (for example, marine navigation systems, gyro compasses, etc.), avionics, security equipment, vehicle head units, industrial or household robots, financial institutions' automatic teller's machines (ATMs), or stores' point of sales (POS) or internet of things (for example, bulbs, various sensors, electric or gas meters, sprinkler systems, fire alarms, thermostats, street lights, toasters, exercise equipment, hot water tanks, heaters, boilers, etc.).

In various embodiments of the present disclosure, an electronic device may include at least one of part of furniture or buildings/structures supporting call forwarding service, electronic boards, electronic signature receiving devices, projectors, and various measuring instruments (for example, water, electricity, gas, or radio signal measuring instruments). An electronic device according to various embodiments of the present disclosure may be one of the above-mentioned various devices or a combination thereof. Additionally, an electronic device according to an embodiment of the present disclosure may be a flexible electronic device. Additionally, an electronic device according to an embodiment of the present disclosure is not limited to the above-mentioned devices and may include a new kind of an electronic device according to the technology development.

Hereinafter, an electronic device according to various embodiments of the present disclosure will be described in more detail with reference to the accompanying drawings. The term “user” in this disclosure may refer to a person using an electronic device or a device using an electronic device (for example, an artificial intelligent electronic device).

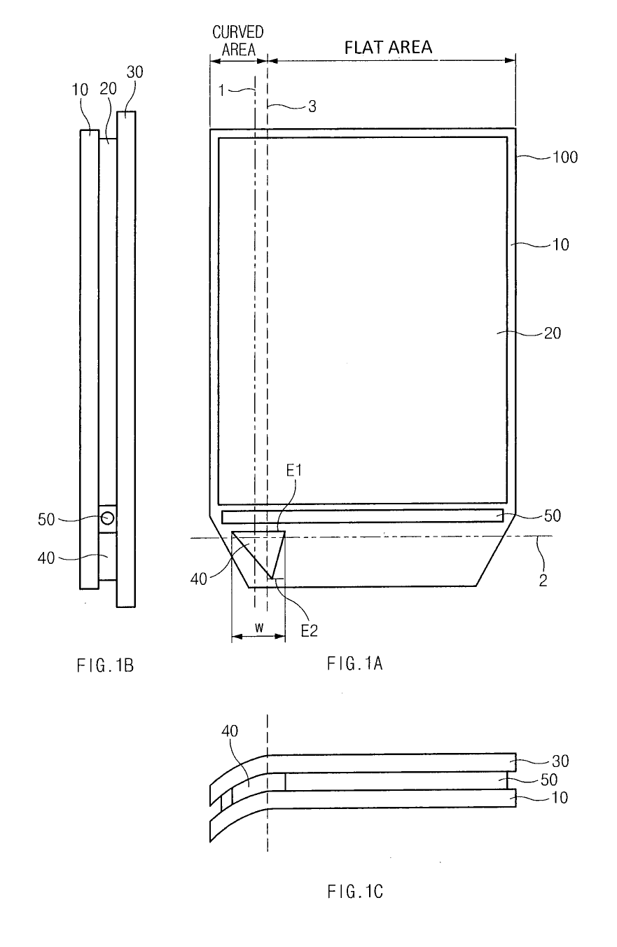

FIG. 1A is a plan view of a display 100, according to various embodiments of the present disclosure. FIG. 1B is a sectional view taken along axis 1 of the display 100 shown in FIG. 1A, according to various embodiments of the present disclosure. FIG. 1C is a sectional view taken along axis 2 of the display 100 shown in FIG. 1A, according to various embodiments of the present disclosure.

According to an embodiment of the present disclosure, the display 100 may include a flat area and a curved (or bended) area. For example, referring to FIGS. 1A, and 1C, the left surface of the display 100 may include a curved area.

Referring to FIGS. 1A to 1C, the display 100 may include one or more of a display panel 10, a polarizing plate 20, a protective panel 30, a step coverage base 40, and a gasket 50.

The display panel 10 may include a display device (for example, a liquid crystal device or an OLED device) for displaying an image by each pixel unit by using light incident from a backlight or light emitted by itself, a thin film transistor (TFT) for switching each pixel, and a signal line connected to an LVDS Display Interface (LDI) for controlling a TFT. According to an embodiment of the present disclosure, the TFT may be manufactured through a low-temperature poly silicon (LTSP) process.

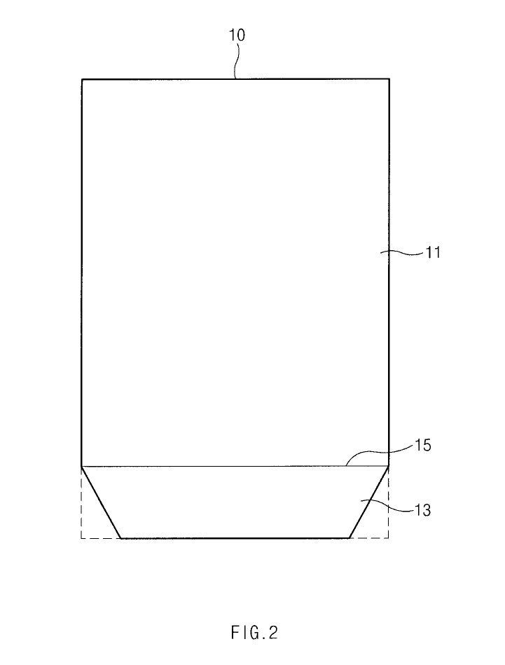

FIG. 2 is a diagram of an example of a display panel according to various embodiments of the present disclosure.

Referring to FIG. 2, the display panel 10 may include a display area (or an active area) 11 and a dummy area 13. The dummy area 13 may extend from at least one side of the display panel 11. For example, referring to FIG. 2, the dummy area 13 may extend from a lower side of the display area 11. The display area 11 may include a display device or a TFT and is an area for actually displaying an image. The dummy area 13 may not display information, but rather it may include an interface for receiving various signals (for example, power or data) necessary for driving a display panel. Referring to FIG. 2, when the dummy area 13 is coupled to an electronic device, in order to create space where another component (for example, a camera module, and so on) would fit, the dummy area 13 may become narrower as it extends from a boundary line 15 of the display area 11.

The polarizing plate 20 may improve the optical performance of the display panel 10 or block at least partially reflections from the panel.

The polarizing plate 20 may be disposed (or formed) at (or over) the top surface of the display panel 10. According to an embodiment of the present disclosure, at least part of the polarizing plate 20 may be formed at the top surface of the display area 11 included in the display panel 10. According to an embodiment of the present disclosure, the polarizing plate 20 may have a larger size than the display area 11 and a portion of the polarizing plate 20 may be disposed over the dummy area 13, as well.

The protective panel 30 may be formed of various materials (for example, glass or plastic) for protecting the display 100 from physical impact. According to an embodiment of the present disclosure, the protective panel 30 may be disposed (or formed) at the top surface of the polarizing plate 20. According to an embodiment of the present disclosure, the protective panel 30 may be disposed at the uppermost layer of the display 100. According to an embodiment of the present disclosure, the protective panel 30 may cover at least some of the display area 11 and/or the dummy area 13 of the display panel 10. In some implementations, the protective panel 30 may have a greater area than the display panel 10 in order for it to be able to cover the entire display panel 10.

The step coverage base 40 is to reduce a stepped portion occurring at the dummy area 13 of the display panel 10 by absence of the polarizing plate 20 and may be manufactured of a plastic material such as PET, a resin of a liquid component, a tape type film, and a polymer material. In other words, the step cover base 40 may be used to fill, at least in part, a gap that might exist between the polarizing plate 20 (or gasket 50), the protective panel 30, and the display panel 10.

The step coverage base 40 may be disposed (or formed) at (or over) the top surface of at least part of the dummy area 13. For example, referring to FIG. 1A, the step coverage base 40 may be disposed at a left partial area of the top surface of the dummy area 13. According to an embodiment of the present disclosure, the step coverage base 40 may be attached to the top surface of the dummy area 13.

According to an embodiment of the present disclosure, the step coverage base 40 may be disposed in a curved area of the display 100. According to an embodiment of the present disclosure, at least part of the step coverage base 40 may be disposed in a flat area and the remaining parts may extend into the curved area. For example, referring to FIG. 1A, the step coverage base 40 may include a boundary 3 of the flat area and the curved area. According to an embodiment of the present disclosure, as the step coverage base 40 extends from the flat area to the curved area, its width W may decrease.

According to an embodiment of the present disclosure, as the step coverage base 40 approaches the polarizing plate 20, its breadth may be disposed to be increased. For example, referring to FIG. 1A, the step coverage base 40 may have a triangular cross-section so that the end E₁ of the step coverage base 40 is broader than the end E₂ of the of the step coverage base. As another example, the step coverage base 40 may have a trapezoidal shape in which the long base is adjacent and/or parallel to the edge of the polarizing plate 20. Additionally or alternatively, the shorter base of the trapezoid may be further away from the polarizing plate than the long base.

Accordingly, a portion that is close to the polarizing plate 20, which receives most of the force generated by a step, may be protected effectively.

According to an embodiment of the present disclosure, the gasket 50 may be interposed between the step coverage base 40 and the polarizing plate 20.

According to an embodiment of the present disclosure, the step coverage base 40 may be disposed in a curved area of the display 100. The step coverage base 40 may have various forms below the height of the polarizing plate 20.

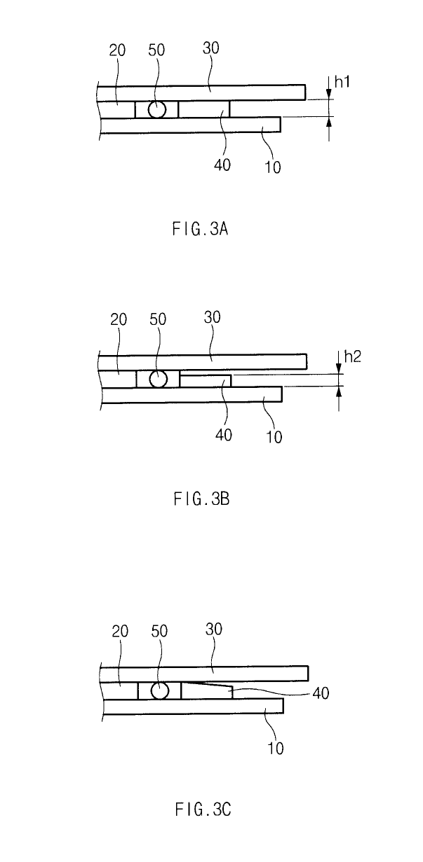

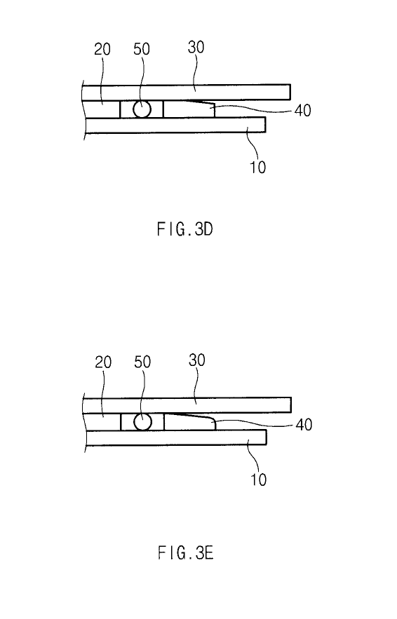

Referring to FIG. 3A, the step coverage base 40 may have a rectangular cross-section and a height h₁ that is substantially the same as the height of the polarizing plate 20. Referring to FIG. 3B, the step coverage base 40 may have a rectangular cross-section and a height h₂ that is lower than the height of the polarizing plate 20. Referring to FIG. 3C, the step coverage base 40 may have one tapered end, such that its height decreases as the step coverage base 40 extends further from the polarizing plate 20. Referring to FIG. 3D, the step coverage base 40 may have the same height as the polarizing plate 20, from the polarizing plate 20 to a specific distance and the height may decrease progressively farther from the polarizing plate 20, from a specific distance. Referring to FIG. 3E, the step coverage base 40 may have a curved top surface, as shown.

The gasket 50 may stop external moisture from flowing into the inside of the display 100 so that it may prevent a corrosion caused by display inside moisture permeability or the weakening of an adhesive strength at a portion fixed by an adhesive. According to an embodiment of the present disclosure, the gasket 50 may be disposed (or formed) parallel to the boundary 15 of the display area 11 and the dummy area 13 at (or over) the top surface of the dummy area 13 of the display panel 10. For example, referring to FIGS. 1A to 1C, the gasket 50 may be disposed long in a horizontal direction at the top surface of the dummy area 13 of the display panel 10.

Additionally or alternatively, in some implementations, the display 100 may include a touch panel disposed at the top surface of the polarizing plate 20, a first adhesive (for example, OCA) disposed between the touch panel and the polarizing plate 20 to bond the touch panel and the polarizing plate, and a second adhesive (for example, OCA) disposed between the touch panel and a protective panel to bond the touch panel and the protective panel. As another example, when the display panel 20 is an LCD panel, the display 100 may further include a second polarizing plate formed at the bottom surface of the display panel 10 and a backlight disposed at the bottom of the second polarizing plate to emit light to the second polarizing plate.

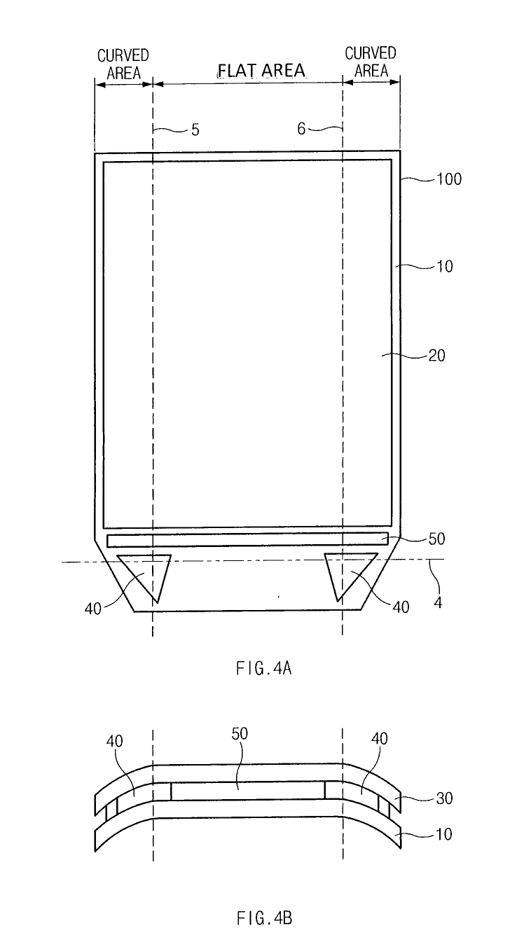

FIG. 4A is a plan view of a display 100, according to various embodiments of the present disclosure. FIG. 4B is a sectional view taken along axis 4 of the display 100 shown in FIG. 4A, according to various embodiments of the present disclosure.

As illustrated in FIG. 4A, the display 100 may include a curved area at the left surface and the right surface. When including a plurality of curved areas, the display 100 may include a plurality of step coverage bases 40 corresponding to the plurality of curved areas. For example, referring to FIG. 4A, the display 100 may include the step coverage base 40 in each partial area of both left and right sides of the top surface of the dummy area 13 of the display panel 10.

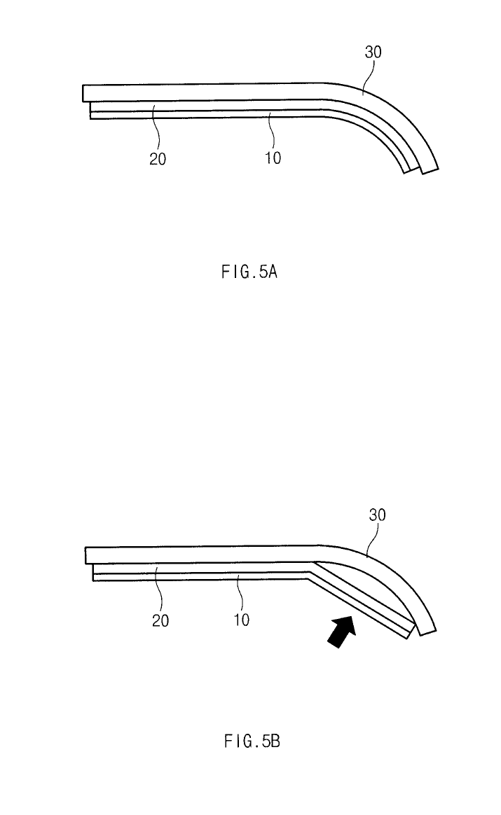

FIG. 5A illustrates an attachment state of a display panel 10, a polarizing plate 20, and a protective panel 30 of a display including a curved area. FIG. 5B illustrates an attachment state of a display panel 10, a polarizing plate 20, and a protective panel 30, which includes manufacturing errors of a display including a curved area.

Referring to FIG. 5A, the display panel 10 and the polarizing plate 20 come in substantially full contact with the protective panel 30 such that no gaps are present between the protective panel 30, the polarizing plate 10, and the display panel 10. When the display panel 10 and the polarizing plate 20 are completely attached to the protective panel 30, even if force is applied to a curved area, the force may be uniformly distributed across the entire curved area.

Referring to FIG. 5B, if a gap may occur between the display panel 10 and the polarizing plate 20, and the protective panel 30. When a gap occurs between the display panel 10 and the protective panel 30, if a force is applied to a curved area, the force may concentrate on a specific area. In the case of a flat area, even if a gap occurs due to manufacturing errors, a force does not concentrate on a specific area, but in the case of a curved area, as shown in FIG. 5B, since a force concentrates on a specific area, the disconnection of a signal line or a fine crack of a panel may occur.

Especially, when a stepped portion occurs due to absence of a polarizing plate in the dummy area 13 of the display panel 10, a force may further concentrate on a specific portion of the display panel 10 in a curved area of the display 100.

According to various embodiments of the present disclosure, the step coverage base 40 may reduce a stepped portion occurring by absence of a polarizing plate in order to prevent the disconnection of a signal line or a fine crack of a panel.

According to various embodiments of the present disclosure, a display may include a flat area and a curved area, a display panel including a display area for displaying an image and a dummy area extending from at least one side surface of the display area, a polarizing plate disposed over a partial area of the display panel including the display area, a protective panel disposed over the polarizing plate, and a step coverage base disposed over at least part of the dummy area to reduce a stepped portion occurring by absence of the polarizing plate. At least part of the step coverage base may be disposed in the curved area.

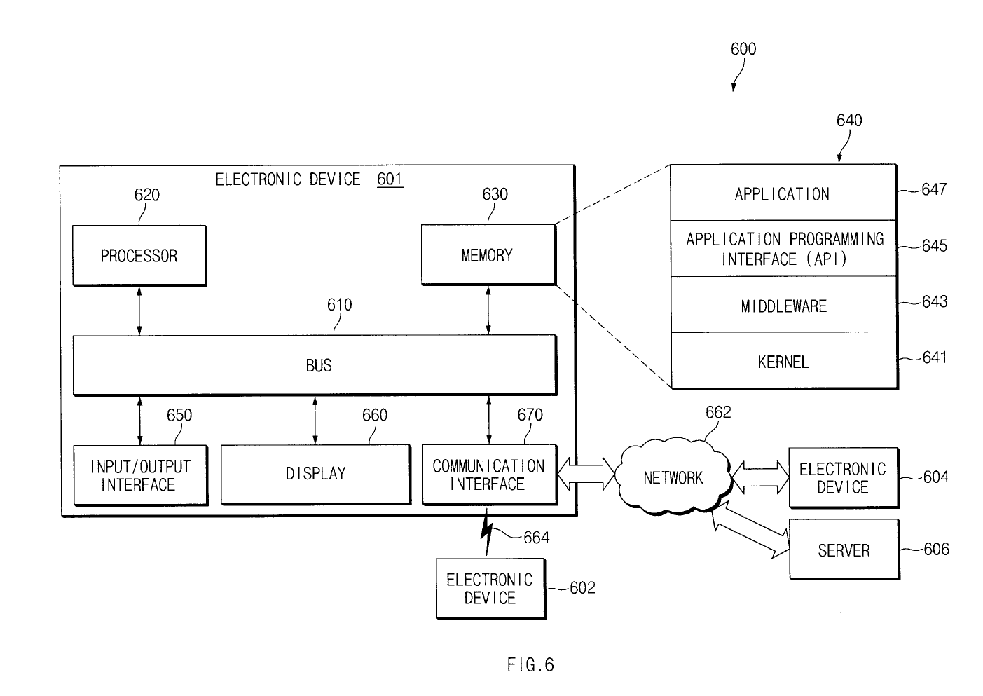

FIG. 6 is a block diagram illustrating an example of an electronic device according to various embodiments of the present disclosure.

Referring to FIG. 6, an electronic device 601 in a network environment 600 is described according to various embodiments of the present disclosure. The electronic device 601 may include a bus 610, a processor 620, a memory 630, an input/output interface 650, a display 660, and a communication interface 670. According to an embodiment of the present disclosure, the electronic device 601 may omit at least one of the components or may additionally include a different component.

The bus 610, for example, may include a circuit for connecting the components 610 to 670 to each other and delivering a communication (for example, control message and/or data) between the components 610 to 670.

The processor 620 may include any suitable type of processing circuitry, such as at least one of a central processing unit (CPU), an Application Processor (AP), and a communication processor (CP). The processor 620, for example, may execute calculation or data processing for control and/or communication of at least one another component of the electronic device 601.

The memory 630 may include volatile and/or nonvolatile memory. The memory 630, for example, may store instructions or data relating to at least one another component of the electronic device 601. According to an embodiment of the present disclosure, the memory 630 may store software and/or programs 640. The program 640 may include a kernel 641, a middleware 643, an application programming interface (API) 645, and/or an application program (or an application) 647. At least part of the kernel 641, the middleware 643, and the API 645 may be called an operating system (OS).

The kernel 641, for example, may control or manage system resources (for example, the bus 610, the processor 620, the memory 630, and so on) used for performing operations or functions implemented in other programs (for example, the middleware 643, the API 645, or the application program 647). Additionally, the kernel 641 may provide an interface for controlling or managing system resources by accessing an individual component of the electronic device 601 from the middleware 643, the API 645, or the application program 647.

The middleware 643, for example, may serve as an intermediary role for exchanging data as the API 645 or the application program 647 communicates with the kernel 641.

Additionally, the middleware 643 may process at least one job request received from the application program 647 according to a priority. For example, the middleware 643 may assign to at least one application program 647 a priority for using a system resource (for example, the bus 610, the processor 620, or the memory 630) of the electronic device 601. For example, the middleware 643 may perform scheduling or load balancing on the at least one job request by processing the at least one job request according to the priority assigned to the at least one job request.

The API 645, as an interface for allowing the application 647 to control a function provided from the kernel 641 or the middleware 643, may include at least one interface or function (for example, an instruction) for file control, protective panel control, image processing, or character control.

The input/output interface 650, for example, may serve as an interface for delivering instructions or data inputted by a user or another external device to another component(s) of the electronic device 601. Additionally, the input/output interface 650 may output instructions or data received from another component(s) of the electronic device 601 to a user or another external device.

The display 660 (for example, the display 100) may include a liquid crystal display (LCD), a light-emitting diode (LED) display, an organic light-emitting diode (OLED) display, a microelectromechanical systems (MEMS) display, or an electronic paper display. The display 660, for example, may display a variety of content (for example, text, image, video, icon, symbol, and so on) to a user. The display 660 may include a touch screen, and for example, may receive a touch, gesture, proximity, or hovering input by using an electronic pen or a user's body part.

The communication interface 670, for example, may set a communication between the electronic device 601 and an external device (for example, the first external electronic device 602, the second external electronic device 604, or the server 606). For example, the communication interface 670 may communicate with an external device (for example, the second external electronic device 604 or the server 606) in connection to the network 662 through wireless communication or wired communication.

The wireless communication, as a cellular communication protocol, may use at least one of long-term evolution (LTE), LTE Advance (LTE-A), code division multiple access (CDMA), wideband CDMA (WCDMA), universal mobile telecommunications system (UMTS), Wireless Broadband (WiBro), Global System for Mobile Communications (GSM), and so on. Additionally, the wireless communication, for example, may include a short range communication 164. The short range communication 164, for example, may include at least one of wireless fidelity (WiFi), Bluetooth (BT), near field communication (NFC), global positioning system (GPS), and so on. The wired communication, for example, may include at least one of universal serial bus (USB), high definition multimedia interface (HDMI), recommended standard 232 (RS-232), plain old telephone service (POTS), and so on. The network 662 may include telecommunications network, for example, at least one of a computer network (for example, LAN or WAN), the Internet, and telephone network.

Each of the first and second external electronic devices 602 and 604 may be the same or different type of the electronic device 601. According to an embodiment of the present disclosure, the server 606 may include a group of one or more servers.

According to various embodiments of the present disclosure, all or part of operations executed on the electronic device 601 may be executed on another one or more electronic devices (for example, the electronic device 602 or 604 or the server 606). According to an embodiment of the present disclosure, when the electronic device 601 performs a certain function or service automatically or by a request, it may request at least part of a function relating thereto from another device (for example, the electronic device 602 or 604 or the server 606) instead of or in addition to executing the function or service by itself. The other electronic device (for example, the external electronic device 602 or 604 or the server 606) may execute a requested function or an additional function and may deliver an execution result to the electronic device 601. The electronic device 601 may provide the requested function or service as it is or by processing the received result additionally. For this, for example, cloud computing, distributed computing, or client-server computing technology may be used.

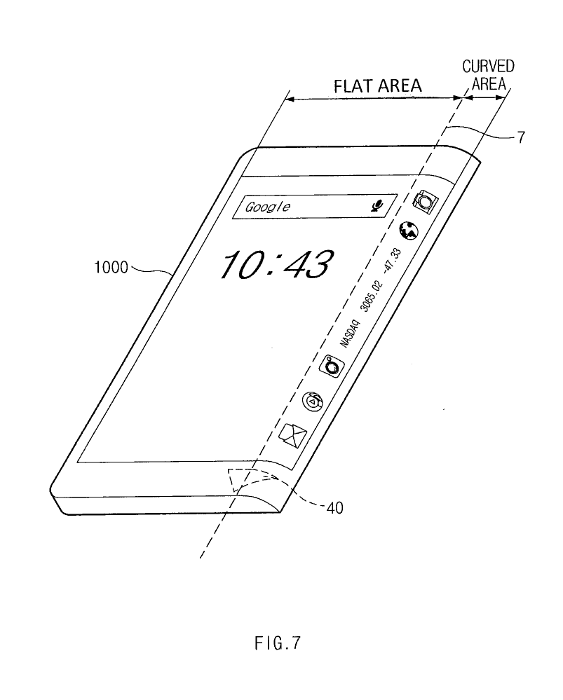

FIG. 7 is diagram showing a perspective view of an example of an electronic device, according to various embodiments of the present disclosure.

According to various embodiments of the present disclosure, an electronic device 1000 (for example, the electronic device 601) may include a display. Since the display is described with reference to FIGS. 1 and 5, its detailed descriptions are omitted.

Referring to FIG. 7, the electronic device 1000 may include a display with a curved area at the right side on the basis of a boundary 7. Referring to FIG. 7, a step coverage base 40 included in the display may be formed at a position including the boundary 7 of a flat area and a curved area.

According to various embodiments of the present disclosure, an electronic device includes a display with a flat area and a curved area. the display includes: a display panel including a display area for displaying an image and a dummy area extending from at least one side surface of the display area; a polarizing plate disposed over a partial area of the display panel including the display area; a protective panel disposed over the polarizing plate; and a step coverage base disposed over at least a portion of the dummy area in order to reduce a stepped portion occurring by absence of the polarizing plate. At least a portion of the step coverage base is disposed in the curved area.

According to various embodiments of the present disclosure, a manufacturing method of a display including a flat area and a curved area includes: disposing a display panel including a display area for displaying an image and a dummy area extending from at least one side surface of the display area; disposing a polarizing plate over a partial area of the display panel including the display area; disposing a protective panel over the polarizing plate; and disposing a step coverage base over at least a portion of the dummy area in order to reduce a stepped portion occurring by absence of the polarizing plate. The disposing of the step coverage base includes disposing at least a portion of the step coverage base in the curved area.

According to various embodiments of the present disclosure, a stepped portion occurring from a display may be compensated effectively.

FIGS. 1-7 are provided as an example only. At least some of the steps discussed with respect to these figures can be performed concurrently, performed in a different order, and/or altogether omitted. It will be understood that the provision of the examples described herein, as well as clauses phrased as “such as,” “e.g.”, “including”, “in some aspects,” “in some implementations,” and the like should not be interpreted as limiting the claimed subject matter to the specific examples.

The above-described aspects of the present disclosure can be implemented in While the present disclosure has been particularly shown and described with reference to the examples provided therein, it will be understood by those skilled in the art that various changes in form and details may be made therein without departing from the spirit and scope of the present disclosure as defined by the appended claims.

What is claimed is:

1. A display apparatus comprising:
a flexible display panel including a display view area and a dummy area around the display view area, wherein the flexible display panel are bended at least on the display view area;
a polarizing plate disposed over the display view area of the flexible display panel and between the flexible display panel and a protective panel;
the protective panel disposed over the polarizing plate; and
a step coverage base disposed over the dummy area of the flexible display panel, alongside to the polarizing plate.

2. The display of claim 1, wherein the entire step coverage base is disposed over a bended portion of the dummy area.

3. The display of claim 1, wherein a first portion of the step coverage base is disposed over a flat portion of the dummy area and a second portion of the step coverage base is disposed over a bended portion of the dummy area.

4. The display of claim 1, wherein the step coverage base has a first surface facing the flexible display panel, and a second surface facing the protective panel, the second surface being inclined relative to the protective panel.

5. The display of claim 1, wherein the step coverage base includes a first end and a second end, the first end being closer to the polarizing plate than the second end, and the first end being wider than the second end.

6. The display of claim 5, wherein the step coverage base has a trapezoidal cross-section, the first end includes the long base of the trapezoid, and the second end includes the short base of the trapezoid.

7. The display of claim 1, further comprising a gasket disposed on a boundary between the display view area and the dummy area, the gasket being interposed between the step coverage base and the polarizing plate.

8. The display of claim 1, further comprising:
a touch panel disposed between the protective panel and the polarizing plate;
a first adhesive disposed between the polarizing plate and the touch panel to bond the protective panel and the touch panel; and
a second adhesive disposed between the touch panel and the protective panel to bond the touch panel and the protective panel.

9. An electronic device comprising a display including:
a flexible display panel including a display view area and a dummy area around the display view area, wherein the flexible display panel are bended at least on the display view area;
a polarizing plate disposed over the display view area of the flexible display panel and between the flexible display panel and a protective panel;
the protective panel disposed over the polarizing plate; and
a step coverage base disposed over the dummy area of the flexible display panel, alongside to the polarizing plate.

10. The electronic device of claim 9, wherein the entire step coverage base is disposed over a bended portion of the dummy area.

11. The electronic device of claim 9, wherein a first portion of the step coverage base is disposed over a flat portion of the dummy area and a second portion of the step coverage base is disposed over a bended portion of the dummy area.

12. The electronic device of claim 11, wherein the step coverage base has a first surface facing the flexible display panel, and a second surface facing the protective panel, the second surface being inclined relative to the protective panel.

13. The electronic device of claim 9, wherein the step coverage base includes a first end and a second end, the first end being closer to the polarizing plate than the second end, and the first end being wider than the second end.

14. The electronic device of claim 13, wherein the step coverage base has a trapezoidal cross-section, the first end includes the long base of the trapezoid, and the second end includes the short base of the trapezoid.

15. The electronic device of claim 9, wherein the display further includes a gasket disposed on a boundary between the display view area and the dummy area, the gasket being interposed between the step coverage base and the polarizing plate.

16. The electronic device of claim 9, wherein the display further comprises:
a touch panel disposed between the protective panel and the polarizing plate;
a first adhesive disposed between the polarizing plate and the touch panel to bond the protective panel and the touch panel; and
a second adhesive disposed between the touch panel and the protective panel to bond the touch panel and the protective panel.

17. A method for manufacturing a display apparatus comprising:
disposing a polarizing plate over a display view area of a flexible display panel, the flexible display panel including the display view area and a dummy area around the display view area, wherein the flexible display panel are bended at least on the display view area;
disposing a protective panel over the polarizing plate; and
disposing a step coverage base over the dummy area of the flexible display panel, alongside to the polarizing plate.

18. The method of claim 17 wherein the entire step coverage base is disposed over a bended portion of the dummy area.

19. The method of claim 17, wherein:
a first portion of the step coverage base is disposed over a flat portion of the dummy area and a second portion of the step coverage base is disposed over a bended portion of the dummy area, and
the step coverage base includes a first surface facing the flexible display panel and a second surface facing the protective panel, the second surface being inclined relative to the protective panel.

20. The method of claim 17, further comprising disposing a gasket on a boundary between the display view area and the dummy area, the gasket being interposed between the step coverage base and the polarizing plate.
